(19) United States
(12) Patent Application Publication
(10) Pub. No.: US 2025/0248203 A1
(43) Pub. Date: Jul. 31, 2025

(54) ORGANIC ELECTROLUMINESCENT DEVICES AND DISPLAY SUBSTRATES

(71) Applicant: BOE TECHNOLOGY GROUP CO., LTD., Beijing (CN)

(72) Inventors: Xiaojin ZHANG, Beijing (CN); Haiyan SUN, Beijing (CN)

(73) Assignee: BOE TECHNOLOGY GROUP CO., LTD., Beijing (CN)

(21) Appl. No.: 18/693,776

(22) PCT Filed: Aug. 10, 2023
(86) PCT No.: PCT/CN2023/112138

§ 371 Date: Mar. 20, 2024

(51) Int. Cl. H10K 50/13; H10K 50/12; H10K 101/00; H10K 101/40

(52) U.S. Cl. CPC H10K 50/13; H10K 50/121; H10K 2101/40; H10K 2101/90

(57) ABSTRACT

An organic electroluminescent device includes a substrate, an anode on the substrate, at least one light emitting unit on a side of the anode away from the substrate, and a cathode located on a side of the light emitting unit away from the anode. The light emitting unit includes a light emitting layer and a light emitting auxiliary layer, wherein the light emitting auxiliary layer is between the anode and the light emitting layer, and the material of the light emitting layer and that of the light emitting auxiliary layer are different. The light emitting layer includes a first host material and a first guest material. The light emitting auxiliary layer includes the first host material.

### CROSS REFERENCE TO RELATED APPLICATIONS

This patent application is a National Stage Entry of PCT/CN2023/112138 filed on Aug. 10, 2023, the disclosure of which is incorporated by reference herein in its entirety as part of the present application.

### TECHNICAL FIELD

The present invention relates to the technical field of touch display, in particular, to an organic electroluminescent device and a method for preparing organic electroluminescent devices.

### BACKGROUND

Sensitized fluorescence technology makes full use of the high efficiency characteristics of sensitizers (such as phosphorescence or thermally-activated delayed fluorescence (TADF) materials) while also taking advantage of the high color purity of fluorescent emitters. Therefore, compared with traditional fluorescence and phosphorescence technologies, sensitized fluorescence technology has more advantages in the display field.

### SUMMARY

Some embodiments of the present invention provide an organic electroluminescent device. The organic electroluminescent device includes an anode, at least one light emitting unit on the anode, and a cathode on a side of the light emitting unit away from the anode, wherein the light emitting unit includes a light emitting layer and a light emitting auxiliary layer, wherein the light emitting auxiliary layer is between the anode and the light emitting layer, wherein a material of the light emitting layer and a material of the light emitting auxiliary layer are different, wherein the light emitting layer includes a first host material and a first guest material, and wherein the light emitting auxiliary layer includes the first host material.

In some embodiments, the light emitting layer includes a green light emitting layer and the green light emitting layer includes the first guest material, the light emitting auxiliary layer includes a green light emitting auxiliary layer and the green light emitting auxiliary layer includes the first host material, and wherein a projection of the green light emitting layer on the anode at least partially overlaps with a projection of the green light emitting auxiliary layer on the anode.

In some embodiments, the first host material includes a hole-type host material. In some embodiments, the green light emitting auxiliary layer further includes the first guest material.

In some embodiments, the green light emitting layer further includes a sensitizer, and wherein the green light emitting auxiliary layer further includes the sensitizer.

In some embodiments, the organic electroluminescent device satisfies:

T1 (hole-type host material)−T1 (sensitizer)≥0.1 eV,
wherein, T1 (hole-type host material) is an energy of a first excited triplet state of the hole-type host material, and T1 (sensitizer) is an energy of the first excited triplet state of the sensitizer.

In some embodiments, the organic electroluminescent device satisfies:

|LUMO (sensitizer)|<|LUMO (hole-type host material)|,
wherein, LUMO (sensitizer) is a lowest unoccupied molecular orbital energy level of the sensitizer, and LUMO (sensitizer) is a lowest unoccupied molecular orbital energy level of the hole-type host material.

In some embodiments, |LUMO (hole-type host material)|−|LUMO (sensitizer)|>0. 3 eV.

In some embodiments, the sensitizer includes a thermally-activated delayed fluorescence (TADF) material, the first guest material includes a fluorescent guest material. Under a normalization condition, an overlapping area of an emission spectrum of the thermally-activated delayed fluorescence material and the absorption spectrum of the first guest material/the area of the absorption spectrum of the first guest material≥60%.

In some embodiments, the hole-type host material includes carbazole materials, and the fluorescent guest material includes boron-containing organic matter.

In some embodiments, the light emitting unit further includes: a hole transport layer between the anode and the light emitting auxiliary layer, and the organic electroluminescent device satisfies:

|HOMO (hole transport layer)−HOMO (first host material)|≤0.3 eV,
wherein HOMO (hole transport layer) is a highest occupied molecular orbital energy level of a material of the hole transport layer, and wherein HOMO (host material) is a highest occupied molecular orbital energy level of the first host material.

In some embodiments, the light emitting unit further includes
a hole injection layer between the anode and the hole transport layer,
a hole blocking layer on a side of the light emitting layer away from the anode,
an electron transport layer on a side of the hole blocking layer away from the anode, and
an electron injection layer on a side of the electron transport layer away from the anode.

In some embodiments, for the electron transport layer and the hole blocking layer of a same light emitting unit,

|LUMO (electron transport layer)|>|LUMO (hole blocking layer)|,
wherein, LUMO (electron transport layer) is a lowest unoccupied molecular orbital energy level of a material of the electron transport layer, and LUMO (hole blocking layer) is a lowest unoccupied molecular orbital energy level of a material of the hole blocking layer.

In some embodiments, the light emitting layer further includes a blue light emitting layer and a red light emitting layer, wherein the blue light emitting layer, the red light emitting layer and the green light emitting layer are spaced apart from each other,
the light emitting auxiliary layer includes a blue light emitting auxiliary layer and a red light emitting auxiliary layer, and wherein the blue light emitting auxiliary layer, the red light emitting auxiliary layer and the green light emitting auxiliary layer are spaced apart from each other,
wherein a projection of the blue light emitting layer on the substrate at least partially overlaps with a projection of the blue light emitting auxiliary layer on the substrate, and wherein a projection of the red light emitting layer on the substrate at least partially overlaps with a projection of the red light emitting auxiliary layer on the substrate.

In some embodiments, the light emitting layer further includes a blue light emitting layer and a red light emitting layer, wherein at least two of a projection of the blue light emitting layer on the anode, a projection of the red light emitting layer on the anode and a projection of the green light emitting layer on the anode partially overlap with each other.

In some embodiments, the red light emitting auxiliary layer includes at least two sub-layers, and in a direction away from the anode and toward the cathode, absolute values of HOMO of materials of the at least two sub-layers increase sequentially. The material mobility of the red light auxiliary sub-layer closer to the cathode is smaller than the material mobility of the red light auxiliary sub-layer farther away from the cathode, and the difference between the two is at least 5 times or more.

In some embodiments, the anode includes plural sub-anodes, wherein a voltage applied to a sub-anode corresponding to the red light emitting layer is different from a voltage applied to a sub-anode corresponding to the blue light emitting layer.

In some embodiments, the voltage applied to the sub-anode corresponding to the red light emitting layer, the voltage applied to the sub-anode corresponding to the blue light emitting layer and a voltage applied to a sub-anode corresponding to the green light emitting layer are all different.

In some embodiments, the organic electroluminescent device satisfies:

T1 (hole blocking layer)>T1 (TADF),
wherein, T1 (hole blocking layer) is an energy of a first excited triplet state of a material of the hole blocking layer, and T1 (TADF) is an energy of the first excited triplet state of the thermally-activated delayed fluorescence material.

In some embodiments, the organic electroluminescent device satisfies:

|LUMO (hole blocking layer)|<|LUMO (light emitting layer)|min,
wherein, LUMO (hole blocking layer) is a lowest unoccupied molecular orbital energy level of a material of the hole blocking layer, and |LUMO (light emitting layer)|min is a smallest of absolute values of lowest unoccupied molecular orbital energy levels of all materials of the light emitting layer.

In some embodiments, |LUMO (light emitting layer)|ₘᵢₙ−|LUMO (hole blocking layer)|≥0.2 eV.

In some embodiments, the organic electroluminescent device satisfies:

|HOMO (hole transport layer)|<|HOMO (blue light emitting auxiliary layer)|<|HOMO (blue light emitting host material)|,
wherein, HOMO (blue light emitting auxiliary layer) is a highest occupied molecular orbital energy level of the material of the blue light emitting auxiliary layer, and HOMO (blue light emitting host material) is a highest occupied molecular orbital energy level of the blue light emitting host material; and
S1 (blue light emitting auxiliary layer)>S1 (blue light emitting layer),
wherein, S1 (blue light emitting auxiliary layer) is an energy of the first singlet state of a material of the blue light emitting auxiliary layer, and S1 (blue light emitting layer) is an energy of a first singlet state of the host material of the blue light emitting layer.

In some embodiments, the blue light emitting layer includes at least one second host material and at least one second guest material, under a normalization condition, an overlapping area of an emission spectrum of the second host material and an absorption spectrum of the second guest material/an area of absorption spectrum of the second guest material≥60%; in some possible embodiments, the second host material has TADF characteristics or phosphorescence characteristics.

The red light emitting layer includes at least one third host material, at least one fourth host material and at least one third guest material, wherein the third host material and the fourth host material are different.

In some embodiments, the second host material includes at least one of the following: anthracenes, fluorenes, pyrenes and their derivatives, D-L-A structure materials, polycarbazole structure materials or metal complex materials.

The second guest material includes at least one of the following: pyrene-based organic matter and boron-containing organic matter;
the blue light emitting auxiliary layer includes carbazole and its derivatives;
the third host material includes an N-type material, and the fourth host material includes a P-type material;
the third guest material includes at least one of a fluorescent material and a phosphorescent material;
the red light emitting auxiliary layer includes carbazole and its derivatives.

In some embodiments, a material of the hole transport layer includes at least one of the following: carbazole and its derivatives;
a material of the hole injection layer includes at least one of the following:
   (1) at least one of CuPc, HATCN and MnO₃; and
   (2) a material of the hole transport layer and P-type dopant, wherein the P-type dopant comprises oxide inorganic materials and/or radialene-based organic materials;
   a material of the electron transport layer includes an electron transport material and a doping material, wherein the doping material includes at least one of LIQ3, Li, and Ca.

In some embodiments, the organic electroluminescent device includes at least two light emitting units.

In some embodiments, the organic electroluminescent device further includes:
at least one charge generation layer located between two adjacent ones of the at least two light emitting units; and
a capping layer on a surface of the cathode away from the light emitting unit.

In some embodiments, a refractive index of the capping layer for a wavelength of 550 nm is >1.8, and wherein a thickness of the capping layer ranges from 50 nm to 100 nm.

Some embodiments of the present invention also provide a method for preparing an organic electroluminescent device as described above, which includes sequentially stacking each layer.

An embodiment of the invention also provides a display substrate. The display substrate includes an organic electroluminescent device on a substrate, the organic electroluminescent device comprising the organic electroluminescent device as described above; and a pixel circuit for controlling the light emission of the organic electroluminescent device.

### BRIEF DESCRIPTION OF THE DRAWINGS

To describe the technical solutions in embodiments of the present disclosure more clearly, the accompanying drawings of embodiments are briefly described below. It should be understood that the drawings described below refer only to some embodiments of the present disclosure, and not to restrict the present disclosure, wherein:

FIG. 1 is a schematic view of an organic electroluminescent device according to an embodiment of the present disclosure;

FIG. 2 is a schematic view of an organic electroluminescent device according to an embodiment of the present disclosure;

FIG. 3 is a schematic view of an organic electroluminescent device according to an embodiment of the present disclosure;

FIG. 4 is a schematic view of an organic electroluminescent device according to an embodiment of the present disclosure;

FIG. 5 is a schematic view of an organic electroluminescent device according to an embodiment of the present disclosure.

FIG. 6 is a schematic view of an organic electroluminescent device according to some embodiments of the present disclosure;

FIG. 7 is a schematic view of an organic electroluminescent device according to an embodiment of the present disclosure; and

FIG. 8 is a schematic view of a display substrate according to an embodiment of the present invention.

### DETAILED DESCRIPTION

In order to make the objectives, technical solutions and advantages of the embodiments of the present disclosure clearer, the technical solutions of the embodiments of the present disclosure will be described clearly and completely in conjunction with the accompanying drawings. Obviously, the described embodiments are part of the embodiments of the present disclosure, rather than all of the embodiments. Based on the described embodiments of the present disclosure, all other embodiments obtained by those skilled in the art without creative labor are also belonging to the protection scope of the present disclosure.

When the elements and the embodiments thereof of the present application are introduced, the articles “a/an”, “one”, “the” and “the” are intended to represent the existence of one or more elements. The expressions “comprise”, “include”, “contain” and “have” are intended as inclusive and mean that there may be other elements besides those listed.

For purposes of the description hereinafter, the terms “upper”, “lower”, “right”, “left”, “vertical”, “horizontal”, “top”, “bottom”, and derivatives thereof shall relate to the invention disclosure, as it is oriented in the drawing figures. The terms “overlying”, “atop”, “positioned on” or “positioned atop” means that a first element, such as a first structure, is present on a second element, such as a second structure, wherein intervening elements, such as an interface structure, e.g. interface layer, may be present between the first element and the second element. The term “direct contact” means that a first element, such as a first structure, and a second element, such as a second structure, are connected with or without any additional elements at the interface of the two elements.

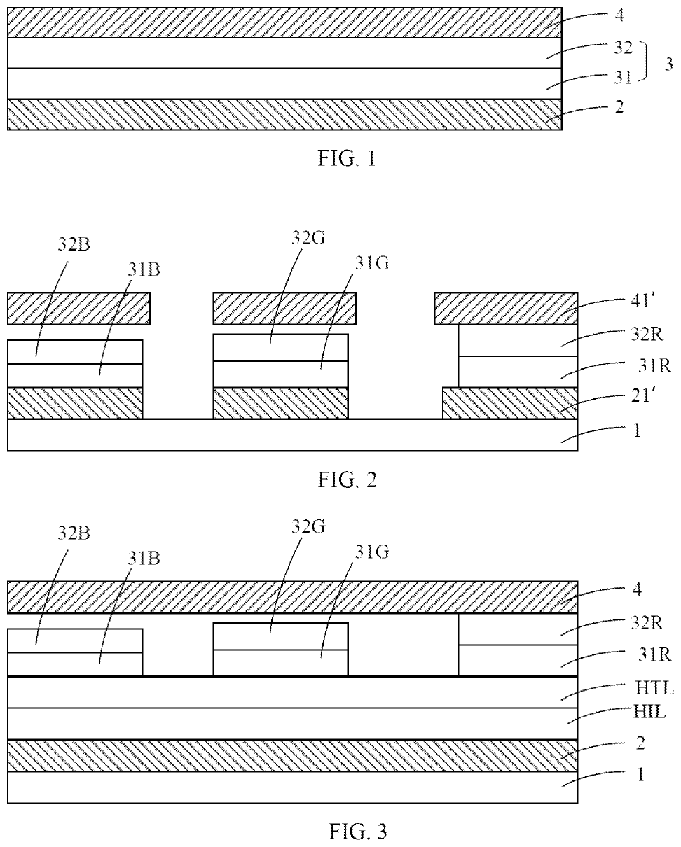

FIG. 1 is a schematic view of an organic electroluminescent device according to an embodiment of the present disclosure. As shown in FIG. 1, an organic electroluminescent device according to an embodiment of the present disclosure may include an anode 2, at least one light emitting unit 3 on the anode 2, and a cathode 4 on a side of the light emitting unit away from the substrate 1. As shown in FIG. 1, the light emitting unit 3 may include a light emitting layer 32 and a light emitting auxiliary layer 31, wherein the light emitting auxiliary layer 31 is between the anode 2 and the light emitting layer 32. A material of the light emitting layer and a material of the light emitting auxiliary layer are different. The light emitting layer may include a first host material and a first guest material, and the light emitting auxiliary layer 32 includes the first host material.

Herein, the material of the light emitting layer and the material of the light emitting auxiliary layer are different means that the materials contained in the two layers are not exactly the same. The light emitting auxiliary layer can be used to prevent excitons in the light emitting layer from diffusing to other layers. For example, the light emitting auxiliary layer can prevent excitons in the light emitting layer from diffusing to the hole transport layer. Therefore, the light emitting auxiliary layer can improve the efficiency of the device and improve the stability of the device.

In conventional technology, four evaporation sources are commonly needed to prepare two different light emitting auxiliary layers to assist the luminescence of the light emitting layer. If only one light emitting auxiliary layer is used, the luminous efficiency is unsatisfactory. However, in some embodiments of the present disclosure, by configuring the light emitting auxiliary layer as including a first host material that also included in the light emitting layer, the evaporation source and the evaporation chamber can be reduced, and the light emitting layer can be assisted by only one light emitting auxiliary layer to emit light with good light emitting efficiency, which reduces manufacturing difficulty and cost.

The organic electroluminescent device may not include a substrate, or the organic electroluminescent device may be configured to include a substrate as needed. The following description takes an organic electroluminescent device including a substrate as an example.

FIG. 2 is a schematic view of an organic electroluminescent device according to an embodiment of the present disclosure. As shown in FIG. 2, in an embodiment according to the present disclosure, the light emitting layer may include a green light emitting layer 32G and the green light emitting layer 31G may include the first guest material. and the light emitting auxiliary layer may include a green light emitting auxiliary layer 31G and the green light emitting auxiliary layer may include the first host material. Wherein a projection of the green light emitting layer 32G on the substrate at least partially overlaps with a projection of the green light emitting auxiliary layer 31G on the substrate 1. A thickness of the green light emitting layer can be used to adjust the green light optical cavity length. The green light emitting auxiliary layer can prevent excitons in the adjacent light emitting layer from diffusing to the hole transport layer, thereby improving efficiency and stability of the device.

The first host material may include a hole-type material. Hole-type host materials have better hole transport properties. For example, the first host material may include TGM (TADF green matrix). In some embodiments, the hole-type host material may include carbazoles. Carbazoles can include mCP, CBP, etc.

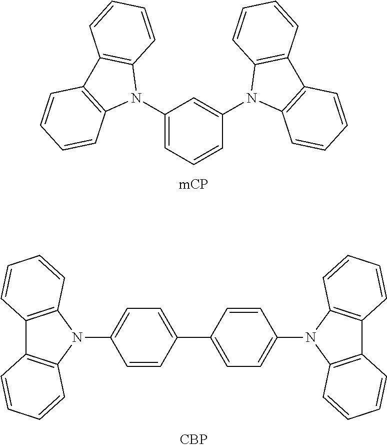 [SMILES: c1cc(-n2c3ccccc3c3ccccc32)cc(-n2c3ccccc3c3ccccc32)c1 ; c1ccc2c(c1)c1ccccc1n2-c1ccc(-c2ccc(-n3c4ccccc4c4ccccc43)cc2)cc1]

In some embodiments, the green light emitting auxiliary layer may further include the aforementioned first guest material. Such a solution can provide devices with lower power consumption.

In some embodiments, the green light emitting layer may include a first host material, a first guest material and a sensitizer. The first guest material may include GD (green dopant). For example, the first guest material may include a fluorescent guest material.

In some embodiments, the sensitizer may include TGH (TADF green host). For example, the sensitizer may include thermally-activated delayed phosphorescence (TADF) materials. Thermally-activated delayed phosphorescence (TADF) materials may include polycarbazole-based materials with a D-L-A structure.

In some embodiments, the activated delayed phosphorescent material and the first guest material may be configured such that the emission spectrum of the activated delayed phosphorescent material and the absorption spectrum of the first guest material have a large overlap area. For example, under a normalization condition, the overlap area of the emission spectrum of the thermally-activated delayed fluorescence material and the emission spectrum of the first guest material/the area of the absorption spectrum of the first guest material is ≥60%.

In some embodiments, the energy of the first excited triplet state of the hole-type host material is higher than the energy of the first excited triplet state of the sensitizer, such as TADF.

In some embodiments, the organic electroluminescent device satisfies:

T1 (hole-type host material)−T1 (sensitizer)≥0.1 eV,
wherein, T1 (hole-type host material) is the energy of the first excited triplet state of the hole-type host material, and T1 (sensitizer) is the energy of the first excited triplet state of the sensitizer.

In some embodiments, the organic electroluminescent device satisfies:

|LUMO (sensitizer)|<|LUMO (hole-type host material)|,
Wherein, LUMO (sensitizer) is the lowest unoccupied molecular orbital energy level of the sensitizer, and LUMO (sensitizer) is the lowest unoccupied molecular orbital energy level of the hole-type host material.

In some embodiments, |LUMO (hole-type host material)|−|LUMO (sensitizer)|>0.3 eV.

FIG. 3 is a schematic view of an organic electroluminescent device according to an embodiment of the present disclosure. As shown in FIG. 3, the organic electroluminescent device according to an embodiment of the present disclosure may further include a hole transport layer (HTL) between the anode 2 and the light emitting auxiliary layer 31. For top-emitting devices, the optical thickness of the organic layer between the cathode and the anode needs to meet the optical path requirements of the optical micro-resonant cavity, so as to obtain the optimal light intensity and required color. Generally, by changing the thickness of the holes that has less impact on the voltage, the internal optical path of the top-emitting device is adjusted.

In some embodiments, the organic electroluminescent device satisfies:

|HOMO (hole transport layer)−HOMO (first host material)|≤0.3 eV,
Wherein HOMO (hole transport layer) is the highest occupied molecular orbital energy level of the hole transport layer material, and HOMO (first host material) is the highest occupied molecular orbital energy level of the first host material. Through such a relatively “deep” HOMO hole transport material, the device voltage can be reduced, especially the green light voltage (for example, it can be significantly reduced by 0.8 eV), and the luminous efficiency of red/blue light is improved, reducing power consumption.

The hole transport layer may include a material with good hole transport properties, i.e., a material with a high hole mobility. For example, the hole mobility of the material of the hole transport layer can be two orders of magnitude higher than its electron mobility. Specifically, for example, the material of the hole transport layer may include at least one of the following: carbazole, aniline and its derivatives. In some embodiments, the thickness of the hole transport layer may range from about 1 nm to 200 nm. For top-emitting devices, the blue optical cavity length can be adjusted by adjusting the thickness of the hole transport layer.

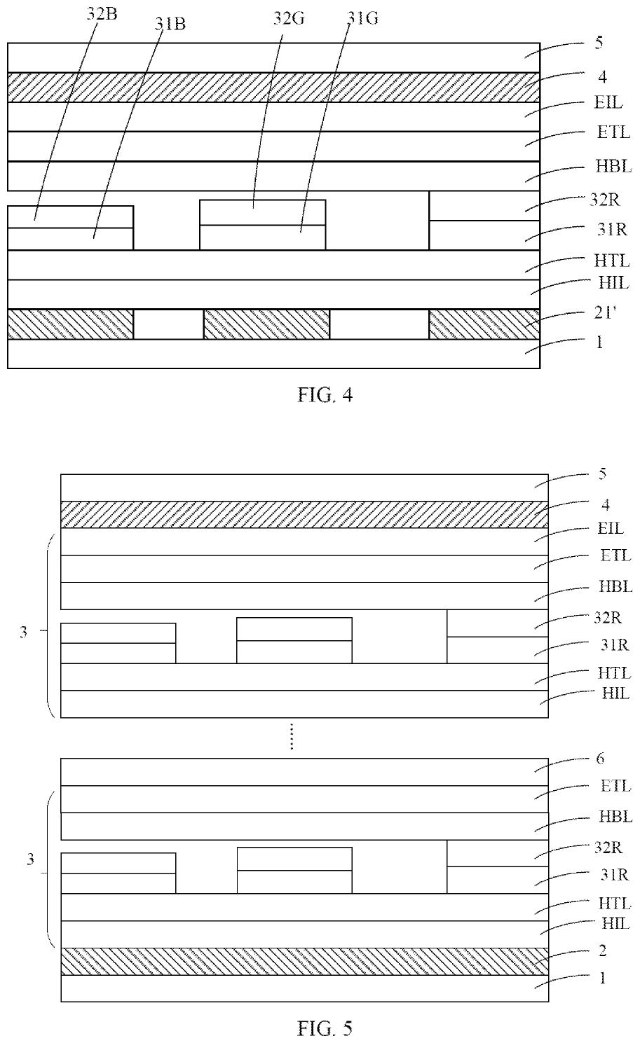

FIG. 4 is a schematic view of an organic electroluminescent device according to an embodiment of the present disclosure. As shown in FIG. 4, the light emitting unit of the organic electroluminescent device according to an embodiment of the present disclosure may further include a hole injection layer (HIL), a hole blocking layer (HBL), an electron transport layer (ETL), an electron injection layer (EIL). As shown in FIG. 4, the hole injection layer (HIL) is located between the anode 2 and the hole transport layer (HTL), and the hole blocking layer (HBL) is located on a side of the light emitting layer (32R, 32B, 32R) away from the anode 2. the electron transport layer (ETL) is located on a side of the hole blocking layer (HBL) away from the anode 2, and the electron injection layer (EIL) is located on a side of the electron transport layer (ETL) away from the anode 2.

The thickness of the hole blocking layer can range from 5 nm to 30 nm. The electron injection layer can be formed by evaporation using low work function metals such as Li, Ca, Yb, or metal salts LiF, LiQ3, etc. The thickness of the electron injection layer can range from 0.5 nm to 2 nm.

For the electron transport layer (ETL) and hole blocking layer (HBL) of a same light emitting unit,

|LUMO (electron transport layer)|>|LUMO (hole blocking layer)|,
wherein, LUMO (electron transport layer) is the lowest unoccupied molecular orbital energy level of the material of the electron transport layer, and LUMO (hole blocking layer) is the lowest unoccupied molecular orbital energy level of the material of the hole blocking layer.

The material of the hole transport layer may include at least one of the following: carbazole and its derivatives.

The material of the hole injection layer may include at least one of the following:
(1) at least one of CuPc, HATCN and MnO₃; and
(2) a material of the hole transport layer and P-type dopant, wherein the P-type dopant comprises oxide inorganic materials and/or radialene-based organic materials;
The material of the electron transport layer comprises an electron transport material and a doping material, wherein the doping material comprise at least one of LIQ3, Li, and Ca. In some embodiments, the electron mobility of the electron transport material is at least two orders of magnitude higher than its hole mobility.

As shown in FIG. 4, the light emitting layer of the organic electroluminescent device may further include a blue light emitting layer 32B and a red light emitting layer 32R, wherein the blue light emitting layer 32B, the red light emitting layer 32R and the green light emitting layer 32G are spaced apart from each other. The light emitting auxiliary layer 31 may include a blue light emitting auxiliary layer 31B and a red light emitting auxiliary layer 31R, wherein the blue light emitting auxiliary layer 31B, the red light emitting auxiliary layer 31R and the green light emitting layer 32G are spaced apart from each other. Wherein, a projection of the blue light emitting layer 32B on the substrate 1 and a projection of the blue light emitting auxiliary layer 31B on the substrate 1 at least partially overlap, and wherein a projection of the red light emitting layer 32R on the substrate 1 at least partially overlaps with a projection of the red light emitting auxiliary layer 31B on the substrate 1.

It should be noted that in the figure, the red light emitting layer 32B and the green light emitting layer 32G are not in contact with the film layer above them (for example, the hole blocking layer HBL) as an example. They can be set to be in contact with the film layers above them as needed. In other embodiments, at least two of the projection of the blue light emitting layer on the anode (or substrate), the projection of the red light emitting layer on the anode (or substrate), and the green light emitting layer on the anode (or substrate) at least partially overlap.

The anode and the cathode correspond to the light emitting sublayers (e.g., green light emitting layer, red light emitting layer, blue light emitting layer) of the light emitting unit to control the light emission of the light emitting sublayers. At least one of the anode and the cathode may include a plurality of sub-electrodes spaced apart from each other (for example, elements 41′ and 21′ in FIGS. 2 and 4). These sub-electrodes can correspond to the sublayers of the light emitting layer through independent patterning designs, and different signals can be input to these sub-electrodes. In some embodiments, at least one of the anode and the cathode is configured to be formed through a whole-layer process, which can achieve the effect of saving process costs.

In some embodiments, the anode includes a plurality of sub-anodes, wherein a voltage applied to the sub-anode corresponding to the red light emitting layer is different from a voltage applied to the sub-anode corresponding to the blue light emitting layer. In some embodiments, the voltage applied to the sub-anode corresponding to the red light emitting layer, the voltage applied to the sub-anode corresponding to the blue light emitting layer and the voltage applied to the sub-anode corresponding to the green light emitting layer are all different.

The red light emitting auxiliary layer can be used to reduce the hole transmission barrier from the adjacent hole transport layer to the red light emitting layer, while ensuring that the excitons of the emitting layer do not overflow. For top-emitting structures, the red light emitting auxiliary layer can also be used to adjust the optical cavity length. In some embodiments, the red light emitting auxiliary layer may include at least two sub-layers, and the absolute values of HOMO of the materials of the at least two sub-layers increase sequentially in a direction away from the anode and toward the cathode.

In some embodiments, the T1 energy of the hole blocking layer material needs to be greater than the T1 energy of the TADF material in the green light emitting layer connected thereto, that is, the organic electroluminescent device satisfies:

T1 (hole blocking layer)>T1 (TADF),
wherein, T1 (hole blocking layer) is the energy of the first excited triplet state of the material of the hole blocking layer, and T1 (TADF) is the energy of the first excited triplet state of the thermally-activated delayed fluorescence material.

In some embodiments, the organic electroluminescent device satisfies:

|LUMO (hole blocking layer)|<|LUMO (light emitting layer)|ₘᵢₙ,
wherein LUMO (hole blocking layer) is the lowest unoccupied molecular orbital energy level of the hole blocking layer material, and |LUMO (light emitting layer)|ₘᵢₙ is the smallest of absolute values of the lowest unoccupied molecular orbital energy levels for all materials of the light emitting layer.

In some embodiments, |LUMO (light emitting layer)|min−|LUMO (hole blocking layer)|≥0.2 eV.

The blue light emitting auxiliary layer can be used to reduce the hole transport barrier from the adjacent hole injection layer to the blue light layer. Therefore, in some embodiments, the highest occupied molecular orbital energy level (HOMO) of material of this layer should be numerically between the HOMO of the adjacent hole transport layer and the HOMO of the main body of the blue light emitting layer, that is, |HOMO (hole transport layer)|<|HOMO (blue light emitting auxiliary layer)|<|HOMO (blue light emitting host material)|. Wherein, HOMO (blue light emitting auxiliary layer) is the highest occupied molecular orbital energy level of the material of the blue light emitting auxiliary layer, and HOMO (blue light emitting host material) is the highest occupied molecular orbital energy level of the host material of the blue light emitting layer.

The blue light emitting auxiliary layer also has an exciton blocking effect. In some embodiments, the singlet first excited state energy S1 of material of this layer is greater than the S1 of the blue light layer material, that is, S1 (blue light emitting auxiliary layer)>S1 (blue light emitting layer). Wherein, S1 (blue light emitting auxiliary layer) is the energy of the first singlet state of the material of the blue light emitting auxiliary layer, and S1 (blue light emitting layer) is the energy of the first singlet state of the material of the blue light emitting layer.

In some embodiments, the blue light emitting layer includes at least one second host material and at least one second guest material (for example, a fluorescent guest material). Under a normalization condition, an overlapping area of an absorption spectrum of the second host material and an absorption spectrum of the second guest material/an area of an absorption spectrum of the second guest material ≥60%. In some possible embodiments, the second host material has TADF characteristics or phosphorescent characteristics. The second host material may include at least one of the following: anthracenes, fluorenes, pyrenes and their derivatives, D-L-A structure materials, polycarbazole structure materials or metal complex materials. The second guest material may include at least one of the following: pyrene-based organic matter and boron-containing organic matter. The doping concentration of the second guest material can be in the range of 0.5˜5% (mass). The main emission peak wavelength of the second guest in the blue light emitting layer is between 450 nm and 480 nm.

In some embodiments, the red light emitting layer includes at least one third host material, at least one fourth host material, and at least one third guest material, wherein the third host material and the fourth host material are different. The third host material may be an N-type material, and the fourth host material may be a P-type material. The third guest material may include at least one of a fluorescent material and a phosphorescent material. The red light emitting auxiliary layer may include carbazole and its derivatives. The thickness of the red light emitting layer can be between 30 nm and 80 nm.

The organic electroluminescent device may further include a capping layer (CPL) 5 on a surface of the cathode 4 away from the substrate 1. The capping layer can be used to increase an optical output. The capping layer can be formed by evaporation of a material with high refractive index and small molecules. For example, for 550 nm light, the refractive index of the capping layer is greater than 1.8. The thickness of the capping layer can be between 50 nm and 100 nm.

The substrate can include various substrate materials, such as glass, sapphire, polyimide, silicon wafer, etc. For bottom-emitting devices, the substrate transmittance needs to be greater than 85% for a wavelength of 550 nm.

The anode can be a high work function electrode material, which can be (1) transparent oxide such as ITO, IZO, etc., with a thickness of 80˜200 nm; (2) Ag/ITO, Al/ITO, Ag/IZO, Al/IZO, etc. to form a composite electrode. The thickness of the metal in the composite electrode is generally 10˜100 nm, and the thickness of the oxide layer is generally 5˜20 nm. If the transparent conductive material in (1) is used as the anode, the device will have a bottom-emitting structure; if the reflective composite electrode in (2) is used, the device will have a top-emitting structure.

The cathode may include a metal with a lower work function (e.g., Al, Ag, Mg, etc.) or an alloy containing a low work function metallic material. For bottom-emitting devices, the cathode thickness can exceed 80 nm to ensure good reflectivity (e.g., >85% @550 nm). For designing top-emitting devices, the thickness of the cathode can be in the range of 10˜20 nm to ensure a certain transmittance (for example, >45% @550 nm).

The organic electroluminescent device may also include an encapsulation layer, such as a UV encapsulant or thin film encapsulation (TFE).

In some embodiments, the organic electroluminescent device may be a tandem light emitting structure, that is, the organic electroluminescent device may include at least two light emitting units. For example, the organic electroluminescent device may include two, three, four or more light emitting units. In some embodiments, the plural light emitting units may be the same. In other embodiments, the plural light emitting units are different. For example, the hole transport layer of one light emitting unit may be different from the hole transport layer of another light emitting unit. For example, the thickness of the layers may differ, the types of materials contained in the layers, or the proportions of materials contained in the layers may differ.

FIG. 5 is a schematic view of an organic electroluminescent device according to an embodiment of the present disclosure. As shown in FIG. 5, in some embodiments, the organic electroluminescent device may further include at least one charge generation layer 6 located between two adjacent light emitting units of the at least two light emitting units. The charge generation layer may include an n-type charge generation layer and/or a p-type charge generation layer. The n-type charge generation layer can be made of ET (electron transport) type materials doped with low work function active metals (for example, LI, Ca, Yb, etc.), and the p-type charge generation layer can generally be made of HT (hole transport) type materials doped with P-type dopants (molybdenum oxide, etc.) It is formed by mixed.

Some embodiments of the present invention also provide a method of preparing an organic electroluminescent device as described above, which includes sequentially stacking each layer.

It should be noted that term “emission spectrum” of a material herein refers to the luminescence spectrum obtained when the material is mixed into a host material at a relatively low ratio (such as 1% to 10%) to prepare a single-layer bottom-emitting OLED device and is powered on. An exemplary device structure is ITO anode/HIL/HTL/EBL/EML (host: material to be tested)/HB/ETL/EIL/Mg: Ag (9:1); or a photoluminescence spectrum of a solid-state film with of the material doped in a wide band gap guest, such as, with a doping concentration of 0.5%˜10%. Description on S1 and T1 of the host material, such as, the host material is in the form of an exciplex containing two components, refers to S1 and T1 of the exciplex. The subsequent description on HOMO and LUMO of the host material, when the host material is in the form of an exciplex, refers to the smaller absolute value HOMO and the larger absolute value LUMO of the two components forming the exciplex respectively.

The present invention will be further described below with reference to specific embodiments.

### Comparative Example 1

In Comparative Example 1, a structure of dual light emitting units is adopted. The R/G/B composition strategy of Comparative Example 1 adopts a series top-emission scheme with a common structure. The B color is determined by the thickness of the hole transport layer including hole transport material (HT1), with a shallow HOMO, of the two light emitting units, and the R color is jointly adjusted by the red light emitting auxiliary layer (R prime) of the two light emitting units. The green light emitting auxiliary layer (G prime) requires two layers, namely, a layer of G prime 1 and a layer of G prime 2. G prime 1 and G prime 2 are made of different materials. Among them, G prime 1 is used to adjust G color, and G prime 2 has a high T1 for exciton blocking to improve efficiency. However, due to the use of a double-layer green light emitting auxiliary layer, the process is more complicated and 4 evaporation sources (corresponding to 2 evaporation chambers of mass production equipment) is required to the prepare two double-layer green light emitting auxiliary layer structures.

### Comparative Example 2

Compared with comparative example 1, there is one green light emitting auxiliary layer less in comparative example 2 than in comparative example 1. Only one green light emitting auxiliary layer (G prime 2) is used for one light emitting unit. Compared with comparative example 1, although the materials and evaporation sources used in the actual EV process in comparative example 2 are reduced, the demand for the evaporation chamber in the mass production process is not different from that of comparative example 1. This is because in order to improve the light emitting efficiency of green light, comparative example 2 requires the use of a green light emitting layer with lower mobility for color compensation adjustment.

### Embodiment 1

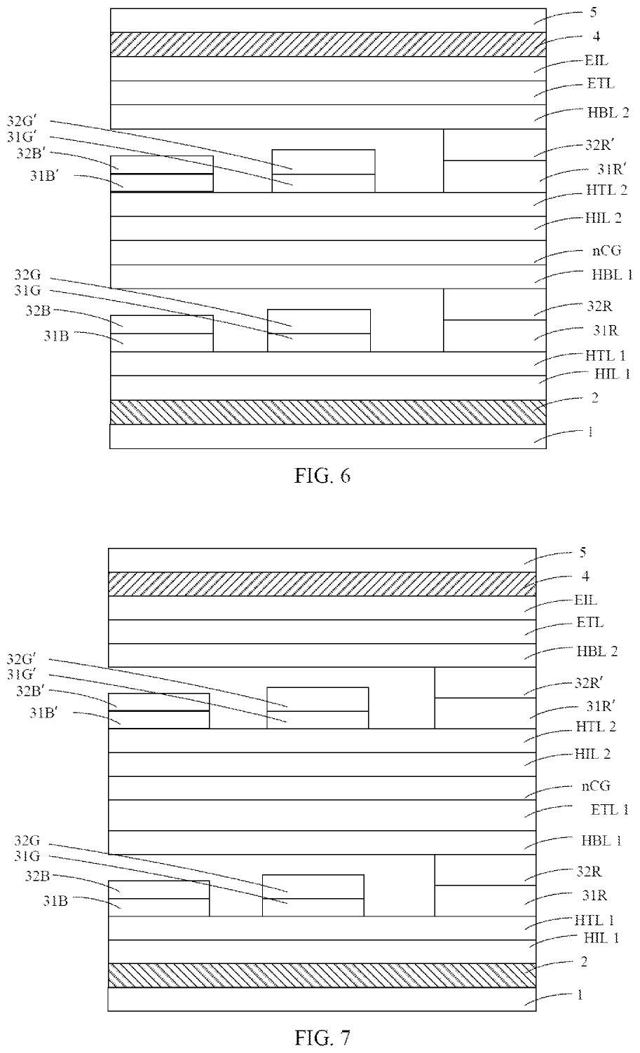

FIG. 6 is a schematic view of an organic electroluminescent device according to some embodiments of the present invention.

The difference between embodiment 1 and the comparative examples mainly lies in the arrangement of the green light emitting auxiliary layer. In embodiment 1, the anode includes a 100 nm thick silver layer and an 8 nm thick ITO layer. The hole injection layer (HIL1) is 10 nm thick and includes the same hole transport material as that contained in the hole transport layer and a p-type dopant, wherein the mass percentage of the p-type dopant in the hole injection layer is 3%. The hole transport layer uses conventional hole transport materials.

The green light emitting layer (32G) includes a host material TGM, a sensitizer TGH, and a guest material GD. The mass ratio of TGM, TGH and GD is 69%: 30%: 1.0%. The green light emitting auxiliary layer (31G) is 5 nm thick and includes TGM.

The red light emitting layer (32R) includes dual host materials (RH-p and RH-n) and a guest material (RD) wherein the mass ratio of RH-p, RH-n and RD is 52%: 45%: 3%. The blue light emitting layer (32B) includes a host material (BH) and a guest material (BD), wherein the mass ratio of BD to the blue light emitting layer is 3%. The thickness of the blue light emitting auxiliary layer (31B) is 5 nm.

The thickness of the hole blocking layer (HBL1) is 5 nm. An n-type charge generation layer (nCG) is provided on the hole blocking layer. The charge generation layer (nCG) is doped with Yb, Wherein the mass percentage of Yb in the n-type charge generation layer is 1%.

A further hole injection layer (HIL2) is provided on the charge generation layer (nCG). The material type of this hole injection layer (HIL2) is the same as that of the underlying hole injection layer (HIL). However, the p-doping concentration thereof is different from that of the underlying hole injection layer (HIL). The mass percentage of the p-type dopant in the further hole injection layer (HIL2) is 10%.

A further hole transport layer (HTL2) is provided on the further hole injection layer (HIL2). In this embodiment, the material of the further hole transport layer (HTL2) is the same as that of the underlying hole transport layer (HTL1).

The green light emitting layer (32G′) includes the host material TGM, the sensitizer TGH, and the guest material GD, wherein the mass ratio of TGM, TGH and GD is 69%: 30%: 1.0%. The green light emitting auxiliary layer (31G′) is 5 nm thick and includes TGM.

The red light emitting layer (32R′) includes dual host materials (RH-p and RH-n) and a guest material (RD), wherein the mass ratio of RH-p, RH-n and RD is 52%: 45%: 3%. The blue light emitting layer (32B′) includes a host material (BH) and a guest material (BD), where the mass ratio of BD to the blue light emitting layer is 3%. The blue light emitting auxiliary layer (31B′) has a thickness of 5 nm.

The hole blocking layer (HBL2) has a thickness of 5 nm.

The electron transport layer (ETL) has a thickness of 35 nm and includes an electron transport material and a doping material LiQ, wherein the mass percentage of the electron transport material and the doping material LiQ is 50%: 50%.

The electron injection layer (EIL) has a thickness of 1 nm.

The cathode includes Mg and Ag, and the thickness of the cathode is 15 nm.

In this embodiment 1, the green light emitting auxiliary layer is a one-layer structure. Compared with conventional solutions, the use of materials can be reduced. Since the green light emitting auxiliary layer includes the host material of the green light emitting layer, the green light emitting auxiliary layer can be formed in the same evaporation chamber as the green light emitting layer. Compared with the conventional solutions, two evaporation chambers can be reduced. From material cost to process difficulty, everything is greatly reduced.

### Embodiment 2

Embodiment 2 further optimizes the hole transport layer and hole injection layer. As shown in the subsequent Table 1, compared with embodiment 1, the HOMO of the hole transport material (denoted as HT2) of embodiment 2 is “deeper”. In embodiment 2, as shown in Table 2 below, the device voltage of embodiment 2, especially the green light voltage, drops significantly by 0.8V. The green light voltage is an acceptable level, and the device efficiency and lifespan are both good. At the same time, after using deep HOMO hole transport materials, the efficiency of R/B light has been improved to a certain extent. Although the luminescence lifespan of B light is reduced by 13%, considering the benefits brought by the efficiency improvement in actual industrial applications (reduced power consumption and little loss of brightness life), the decrease in lifespan is acceptable.

### Embodiment 3

Compared with embodiment 2, embodiment 3 changes the arrangement of the green light emitting auxiliary layer. In embodiment 3, the green light emitting auxiliary layer includes the light emitting host material TGM and the light emitting guest material GD of the green light emitting layer. In embodiment 3, the mass of the luminescent guest material GD accounts for 1.5% of the mass of the green light emitting auxiliary layer. The green light emitting auxiliary layer has a thickness of 5 nm.

Compared with embodiment 2, embodiment 3 uses two green light emitting layer materials, TGM and GD, as the green light emitting auxiliary layer. The device characteristics thereof are similar to those of embodiment 2, and it also achieves good technical effects.

### Embodiment 4

FIG. 7 is a schematic view of an organic electroluminescent device according to an embodiment. As shown in FIG. 7, compared with embodiment 2, the solution of embodiment 4 is provided with an additional electron transport layer (ETL1). The electron transport layer (ETL1) is located between the charge generation layer (nCG) and the hole blocking layer (HBL1). The electron transport layer (ETL1) includes electron transport materials and doping materials, wherein the doping materials include LiQ (8-hydroxyquinolinolato-lithium).

Compared with the solution of embodiment 2, the device voltage of embodiment 4 is significantly reduced, while the device efficiency and lifespan are also maintained at a good level.

### Embodiment 5

Compared with embodiment 2, embodiment 5 changes the arrangement of the green light emitting auxiliary layer. In embodiment 5, the green light emitting auxiliary layer (31G, 31G′) includes the light emitting host material TGM of the green light emitting layer (32G, 32G′) and the sensitizer material TGH of the green light emitting layer. In embodiment 5, the sensitizer material TGH accounts for 30% of the mass of the green light emitting auxiliary layer. The green light emitting auxiliary layer has a thickness of 5 nm.

Compared with embodiment 2, in embodiment 5, the green light emitting auxiliary layer includes two green light emitting layer materials, TGM and TGH, and the efficiency of the green light emitting device decreases to a certain extent. The reason for this decrease is that TGH, as a triplet generation center, causes exciton leakage. However, this solution also has lifespan advantages and is valuable in certain specific scenarios that emphasize lifespan.

### Embodiment 6

Compared with embodiment 5, the materials of the two green light emitting auxiliary layers of the two light emitting units of embodiment 6 are different. The green light emitting auxiliary layer 31G closer to the anode includes the luminescent host material TGM of the green light emitting layer 32G and the sensitizer material TGH of the green light emitting layer 32G. The sensitizer material TGH accounts for 30% of the mass of the green light emitting auxiliary layer. The thickness of the green light emitting auxiliary layer 31G is 5 nm. The green light emitting auxiliary layer 31G′ closer to the cathode does not include the material of the green light emitting layer 32G′.

Compared with solution 2, the voltage of green light in embodiment 6 has decreased, but there is basically no difference in efficiency and lifespan. However, compared with embodiment 2, this solution requires an additional evaporation source corresponding to the material of the green light emitting auxiliary layer 31G′, and the process complexity is increased. However, compared with the comparative example, the process of this embodiment is still simplified.

The characteristic parameters of some materials are as follows:

TABLE 1
Partially related to the molecular orbital energy
levels and excited state energies of materials

| | HOMO | LUMO | T1 | S1 | PL |
|---|---|---|---|---|---|
| | (eV) | (eV) | (eV) | (eV) | peak(nm) |
| HT1 | −5.3 | −2.3 | / | / | / |
| HT2 | −5.6 | −2.5 | / | / | / |
| B prime | −5.7 | −2.5 | 2.6 | / | / |
| G prime1 | −5.5 | −2.5 | / | / | / |
| G prime2 | −5.7 | −2.6 | 2.8 | / | / |
| R prime | −5.6 | −2.5 | 2.6 | / | / |
| BH | −6.0 | −3.0 | N.D. | / | / |
| RH-p | −5.3 | −2.4 | / | / | / |
| RH-n | −5.9 | −2.8 | / | / | / |
| TGM | −5.8 | −2.5 | 2.7 | 3.3 | 350 |
| TGH | −6.0 | −3.6 | 2.52 | 2.57 | 510 |
| GD | −5.8 | −3.4 | 2.1 | 2.4 | 525 |
| HB | −6.4 | 2.4 | 2.59 | / | / |
| ET | −6.6 | −2.7 | / | / | / |

Wherein, the S1 and T1 of the material are respectively derived from the energy corresponding to the peaks of the fluorescence spectrum and phosphorescence spectrum obtained by the dilute solution of the material at ≤77K.

The characteristics of comparative example 1-2 and embodiments 1-6 are as follows:

TABLE 2
Device Characteristics

| | | Current | | | Color | |
|---|---|---|---|---|---|---|
| | Device | density | Voltage | Efficiency | coordinate | LT95 |
| | ID | (mA/cm2) | (V) | (cd/A) | (CIE-1931) | lifespan |
| Comparative | R | 15 | 7.0 | 100% | 0.685, 0.315 | 100% |
| example 1 | B | 15 | 7.3 | 100% | 0.141, 0.042 | 100% |
| | G | 15 | 7.1 | 100% | 0.210, 0.746 | 100% |
| Comparative | R | 15 | 7.0 | 100% | 0.685, 0.315 | 100% |
| example 2 | B | 15 | 7.3 | 100% | 0.141, 0.042 | 100% |
| | G | 15 | 7.3 | 96% | 0.210, 0.746 | 105% |
| Embodiment | R | 15 | 7.0 | 100% | 0.685, 0.325 | 100% |
| 1 | B | 15 | 7.3 | 100% | 0.141, 0.042 | 100% |
| | G | 15 | 8.3 | 69% | 0.206, 0.748 | 117% |
| Embodiment | R | 15 | 6.9 | 101% | 0.683, 0.317 | 98% |
| 2 | B | 15 | 7.2 | 107% | 0.140, 0.040 | 87% |
| | G | 15 | 7.5 | 95% | 0.208, 0.747 | 105% |
| Embodiment | R | 15 | 6.9 | 103% | 0.683, 0.317 | 98% |
| 3 | B | 15 | 7.2 | 107% | 0.140, 0.040 | 87% |
| | G | 15 | 7.5 | 96% | 0.140, 0.040 | 105% |
| Embodiment | R | 15 | 6.8 | 103% | 0.685, 0.315 | 95% |
| 4 | B | 15 | 7.0 | 110% | 0.206, 0.749 | 85% |
| | G | 15 | 7.3 | 96% | 0.141, 0.043 | 104% |
| Embodiment | R | 15 | 6.9 | 101% | 0.683, 0.317 | 98% |
| 5 | B | 15 | 7.2 | 107% | 0.140, 0.040 | 87% |
| | G | 15 | 7.6 | 78% | 0.204, 0.749 | 109% |
| Embodiment | R | 15 | 6.9 | 101% | 0.683, 0.317 | 98% |
| 6 | B | 15 | 7.2 | 107% | 0.140, 0.040 | 87% |
| | G | 15 | 7.4 | 99% | 0.210, 0.747 | 102% |

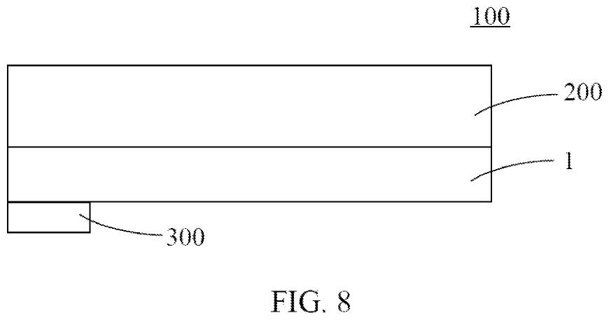

FIG. 8 is a schematic view of a display substrate according to an embodiment of the present invention. As shown in FIG. 8, the display substrate may include an organic electroluminescent device 200 and a pixel circuit 300 on a substrate 1. The organic electroluminescent device 200 may be the organic electroluminescent device shown in FIGS. 1-7, and the pixel circuit 300 is for controlling the organic electroluminescent device to emit light. In some embodiments, pixel circuit 300 and the organic electroluminescent device 200 may be on the same side of the substrate. In other embodiments, the pixel circuit 300 and the organic electroluminescent device 200 are located on different sides of the substrate.

Certain specific embodiments have been described, and these embodiments are only shown by way of example and are not intended to limit the scope of the present disclosure. In fact, the novel embodiments described herein can be implemented in various other forms; in addition, various omissions, substitutions and changes in the form of the embodiments described herein can be made without departing from the spirit of the present disclosure. The appended claims and their equivalents are intended to cover such forms or modifications that fall within the scope and spirit of the present disclosure.

1. An organic electroluminescent device, comprising:
an anode,
at least one light emitting unit on the anode, and
a cathode on a side of the light emitting unit away from the anode, wherein the light emitting unit comprises:
a light emitting layer and
a light emitting auxiliary layer, wherein the light emitting auxiliary layer is between the anode and the light emitting layer, wherein a material of the light emitting layer and a material of the light emitting auxiliary layer are different, wherein the light emitting layer comprises a first host material and a first guest material, and wherein the light emitting auxiliary layer comprises the first host material.

2. The organic electroluminescent device according to claim 1, wherein the light emitting unit comprises a green light emitting unit, the green light emitting unit comprises a green light emitting layer comprising the first guest material, the light emitting auxiliary layer comprises a green light emitting auxiliary layer comprising the first host material, and wherein a projection of the green light-emitting layer on the anode at least partially overlaps with a projection of the green light emitting auxiliary layer on the anode.

3. The organic electroluminescent device according to claim 2, wherein the first host material comprises a hole-type host material.

4. The organic electroluminescent device according to claim 3, wherein the green light emitting auxiliary layer further comprises the first guest material.

5. The organic electroluminescent device according to claim 3, wherein the green light emitting layer further comprises a sensitizer, and wherein the green light emitting auxiliary layer further comprises the sensitizer.

6. The organic electroluminescent device according to claim 5, satisfying:
T1 (hole-type host material)−T1 (sensitizer)≥0.1 eV,
wherein, T1 (hole-type host material) is an energy of a first excited triplet state of the hole-type host material, and T1 (sensitizer) is an energy of the first excited triplet state of the sensitizer.

7. The organic electroluminescent device according to claim 5, satisfying:

|LUMO (sensitizer)|<|LUMO (hole-type host material)|,
wherein, LUMO (sensitizer) is a lowest unoccupied molecular orbital energy level of the sensitizer, and LUMO (sensitizer) is a lowest unoccupied molecular orbital energy level of the hole-type host material.

8. The organic electroluminescent device according to claim 7, wherein,

|LUMO (hole-type host material)|−|LUMO (sensitizer)|>0. 3 eV.

9. The organic electroluminescent device according to claim 5, wherein the sensitizer comprises a thermally-activated delayed fluorescence (TADF) material, the first guest material comprises a fluorescent guest material, and under a normalization condition, an overlapping area of an emission spectrum of the thermally-activated delayed fluorescence material and the absorption spectrum of the first guest material/an area of the absorption spectrum of the first guest material≥60%.

10. The organic electroluminescent device according to claim 9, wherein the hole-type host material comprises carbazole materials, and the fluorescent guest material comprises a boron-containing organic matter.

11. The organic electroluminescent device according to claim 1, wherein the light emitting unit further comprises a hole transport layer between the anode and the light emitting auxiliary layer, and wherein the organic electroluminescent device satisfies:

|HOMO (hole transport layer)−HOMO (first host material)|≤0.3 eV,
wherein, HOMO (hole transport layer) is a highest occupied molecular orbital energy level of a material of the hole transport layer, and wherein HOMO (first host material) is a highest occupied molecular orbital energy level of the first host material.

12. The organic electroluminescent device according to claim 11, wherein the light emitting unit further comprises:
a hole injection layer between the anode and the hole transport layer;
a hole blocking layer on a side of the light emitting layer away from the anode;
an electron transport layer on a side of the hole blocking layer away from the anode; and
an electron injection layer on a side of the electron transport layer away from the anode.

13. The organic electroluminescent device according to claim 12, for the electron transport layer and the hole blocking layer of a same light emitting unit, satisfying:

|LUMO (electron transport layer)|>|LUMO (hole blocking layer)|,
wherein, LUMO (electron transport layer) is a lowest unoccupied molecular orbital energy level of a material of the electron transport layer, and LUMO (hole blocking layer) is a lowest unoccupied molecular orbital energy level of a material of the hole blocking layer.

14. The organic electroluminescent device according to claim 12, wherein the light emitting layer further comprises
a blue light emitting layer and
a red light emitting layer, wherein the blue light emitting layer, the red light emitting layer and the green light emitting layer are spaced apart from each other;
the light emitting auxiliary layer comprises
a blue light emitting auxiliary layer and
a red light emitting auxiliary layer, and wherein the blue light emitting auxiliary layer, the red light emitting auxiliary layer and the green light emitting auxiliary layer are spaced apart from each other,
wherein a projection of the blue light emitting layer on the anode at least partially overlaps with a projection of the blue light emitting auxiliary layer on the anode, and wherein a projection of the red light emitting layer on the anode at least partially overlaps with a projection of the red light emitting auxiliary layer on the anode,
or
the light emitting layer further comprises
a blue light emitting layer and
a red light emitting layer, wherein at least two of a projection of the blue light emitting layer on the anode, a projection of the red light emitting layer on the anode and a projection of the green light emitting layer on the anode partially overlap with each other.

15. (canceled)

16. The organic electroluminescent device according to claim 14, wherein the red light emitting auxiliary layer comprises at least two sub-layers, and in a direction away from the anode and toward the cathode, absolute values of HOMO of materials of the at least two sub-layers increase sequentially.

17-18. (canceled)

19. The organic electroluminescent device according to claim 9, satisfying:
T1 (hole blocking layer)>T1 (TADF),
wherein, T1 (hole blocking layer) is an energy of a first excited triplet state of a material of the hole blocking layer, and T1 (TADF) is an energy of the first excited triplet state of the thermally-activated delayed fluorescence material; and

|LUMO (hole blocking layer)|≤|LUMO (light emitting layer)|ₘᵢₙ,
wherein, LUMO (hole blocking layer) is a lowest unoccupied molecular orbital energy level of a material of the hole blocking layer, and |LUMO (light emitting layer)|ₘᵢₙ is a smallest of absolute values of lowest unoccupied molecular orbital energy levels of all materials of the light emitting layer.

20. (canceled)

21. The organic electroluminescent device according to claim 19, wherein

|LUMO (light emitting layer)|ₘᵢₙ−|LUMO (hole blocking layer)|≥0.2 eV.

22. The organic electroluminescent device according to claim 14, satisfying:

|HOMO (hole transport layer)|<|HOMO (blue light emitting auxiliary layer)|<|HOMO (blue light emitting host material)|,
wherein, HOMO (blue light emitting auxiliary layer) is a highest occupied molecular orbital energy level of the material of the blue light emitting auxiliary layer, and HOMO (blue light emitting host material) is a highest occupied molecular orbital energy level of the blue light emitting host material; and
S1 (blue light emitting auxiliary layer)>S1 (blue light emitting layer),
wherein, S1 (blue light emitting auxiliary layer) is an energy of the first singlet state of a material of the blue light emitting auxiliary layer, and S1 (blue light emitting layer) is an energy of a first singlet state of the host material of the blue light emitting layer.

23. The organic electroluminescent device according to claim 14, wherein,
the blue light emitting layer comprises
at least one second host material and
at least one second guest material, wherein under a normalization condition, an overlapping area of an emission spectrum of the second host material and an absorption spectrum of the second guest material/an area of absorption spectrum of the second guest material≥60%, and the second host material has at least one of a characteristic of a thermally-activated delayed fluorescence material and a characteristic of a phosphorescent material; and wherein,
the red light emitting layer comprises
at least one third host material,
at least one fourth host material and
at least one third guest material, wherein the third host material and the fourth host material are different.

24-28. (canceled)

29. A display substrate, comprising:
an organic electroluminescent device on a substrate, the organic electroluminescent device comprising the organic electroluminescent device according to claim 1; and
a pixel circuit for controlling the light emission of the organic electroluminescent device.
